(19) United States
(12) Patent Application Publication
(10) Pub. No.: US 2014/0084428 A1
(43) Pub. Date: Mar. 27, 2014

(54) INTEGRATED CIRCUIT WITH ELECTRICAL THROUGH-CONTACT AND METHOD FOR PRODUCING ELECTRICAL THROUGH-CONTACT

(71) Applicants: Harry Hedler, Germering (DE); Markus Schieber, München (DE); Stefan Wirth, Erlangen (DE); Jörg Zapf, München (DE)

(72) Inventors: Harry Hedler, Germering (DE); Markus Schieber, München (DE); Stefan Wirth, Erlangen (DE); Jörg Zapf, München (DE)

(73) Assignee: SIEMENS AKTIENGESELLSCHAFT, München (DE)

(21) Appl. No.: 14/006,913

(22) PCT Filed: Mar. 7, 2012
(86) PCT No.: PCT/EP12/53849

§ 371 Date: Dec. 3, 2013

(30) Foreign Application Priority Data
Mar. 23, 2011 (DE) 10 2011 005 978.4

(51) Int. Cl. H01L 23/48; H01L 21/768

(52) U.S. Cl. CPC H01L 23/481; H01L 21/76898
USPC 257/621; 438/667

(57) ABSTRACT

A substrate of an integrated circuit has a first surface and an opposing second surface. A functionalized region is formed at least on the first surface. At least one electrical through-plating is provided as a through-hole which is continuously filled with an electrically conductive material and which runs from the first surface to the second surface through the substrate. To ensure that the through-plating can be reliably produced and is provided in a space-saving manner, the through-hole has at least one gradation on which a transition occurs from a smaller hole cross-section on the side of the first surface to a larger hole cross-section on the side of the second surface.

### CROSS REFERENCE TO RELATED APPLICATIONS

This application is the U.S. national stage of International Application No. PCT/EP2012/053849, filed Mar. 7, 2013 and claims the benefit thereof. The International Application claims the benefit of German Application No. 10 2011 005 978.4 filed on Mar. 23, 2011, both applications are incorporated by reference herein in their entirety.

### BACKGROUND

Described below are an integrated circuit and a method for producing an electrical through-contact. An integrated circuit and a method for producing an electrical through-contact are known from DE 10 2006 035 864 A1, for example, in which a microelectronically integrated circuit is formed by stacking a plurality of substrates each having a microelectronically functionalized region, wherein (at least) one of the substrates is provided with (at least) one electrical through-contact in order to enable signal or else power connection paths from one substrate to another substrate of the substrate stack or else out of the integrated circuit. In particular, in this case electrical through-contacts are provided which are formed in each case as a through-hole extending from a first substrate surface to an opposite second substrate surface through the relevant substrate and filled continuously with an electrically conductive material.

In DE 10 2006 035 864 A1 it is noted with regard to an “aspect ratio” of such holes in a substrate, that is to say the ratio between hole depth and hole width (hole diameter), that the aspect ratio is in a range of from 2 to 10, but is typically greater than 3.

In this respect, the following should be noted: in order to reduce the area and/or volume requirement of an electrical through-contact of the known type, it has already been attempted to produce the through-hole in the substrate with an aspect ratio of more than 10 or accordingly with a “very small diameter”. However, this approach for miniaturization of the through-contact has failed heretofore owing to numerous technological problems.

In particular, in the case of larger aspect ratios, the filling process (filling with electrically conductive material) is made extremely difficult and slowed down extremely. Moreover, inhomogeneities or an incomplete filling can result. In practice, therefore, in particular continuous and fault-free filling “forming a unified whole” is prevented in the case of a particularly large aspect ratio.

Another approach for miniaturization reduced the hole diameter with a predefined aspect ratio, by reducing the thickness of the substrate. However, in practice technological limits are likewise imposed on such “thinning” of the substrates or wafers. Moreover (with an aspect ratio not all that small) a particularly small hole cross section can again prevent fault-free continuous filling.

### SUMMARY

In the case of an integrated circuit of the type mentioned in the introduction, the method described below simply and reliably produces an advantageously space-saving electrical through-contact.

In an integrated circuit produced by the method described below, the through-hole has at least one gradation at which a transition takes place from a smaller hole cross section on the part of the first surface to a larger hole cross section on the part of the second surface.

The method described below includes forming a through-hole having a hole cross section that varies, as viewed over the hole length, in such a way that in favor of a technologically less problematic filling process a larger hole cross section is indeed provided, but it undergoes transition to a smaller hole cross section in the region of at least one gradation in favor of a reduction of the area requirement in the functionalized substrate region.

The method thus makes it possible to provide an electrical through-contact having a small space requirement (in the relevant region) and nevertheless outstanding quality and reliability both with regard to the production process and with regard to the later function. Advantageously, the continuous filling of the through-hole with the electrically conductive material, which is important for the later function, is accomplished “so as to form a unified whole”, i.e. continuously over the entire hole length between the two relevant substrate surfaces with high process reliability.

The through-hole can have one or a plurality of such cross-section-changing gradations, wherein a very abrupt cross-section change may take place at each gradation (e.g. over a transition region as viewed in the longitudinal direction of the hole of less than 10% of the total length of the hole).

The terms “smaller hole cross section” and “larger hole cross section” relate here to the difference between the hole cross sections on both sides of the relevant gradation.

It is often advantageous if, during or after the production of the through-hole, its circumferential surface is firstly “passivated” i.e. provided with an electrical insulation, before the electrically conductive material is introduced. In the case of a through-hole in a silicon substrate, the passivation can be formed by a silicon oxide layer, for example.

The through-hole may have a circular hole cross section. Dimensions or dimensioning rules are indicated below with regard to such a circular hole cross section. It goes without saying that corresponding dimensions and dimensioning rules with regard to the corresponding hole cross sections (surfaces) are thus also disclosed, which in each case should be inferred in the case of the indications below (and can also be applied to non-circular hole cross sections).

In one embodiment it is provided that a diameter of the smaller hole cross section is less than 20 μm, in particular less than 10 μm. On the other hand, the diameter may be at least one 1 μm or at least 2 μm, for example approximately 5 μm.

In one embodiment it is provided that a diameter of the smaller hole cross section is less than 200%, in particular less than 100%, of the height of the functionalized region. The height of the functionalized region can be in the range of 1 μm to 20 μm, for example. If the functionalized region has a non-uniform height as viewed over its lateral extent, then the term “height of the functionalized region” used here relates to that height which is present in the direct vicinity of the relevant opening of the through-hole.

In one embodiment it is provided that the diameters of the smaller hole cross section and of the larger hole cross section differ from one another by at least a factor of 2, or at least a factor of 5.

In one embodiment, a diameter of the larger hole cross section is greater than 30 μm, in particular greater than 60 μm. On the other hand, the diameter may be less than 200 μm, for example approximately 100 μm.

As already mentioned, the through-hole can also have more than one gradation at which the hole cross section or hole diameter changes. If more than one gradation is provided, then the indications indicated above concerning the “smaller hole cross section” relate to the hole cross section extending directly to the first substrate surface, that is to say as it were the “smallest hole cross section of all” in this multi-step design. By contrast, in this case the “larger hole cross section” denotes the hole cross section extending directly to the second surface, that is to say as it were the “largest hole cross section of all” in the multi-step design.

In one embodiment it is provided that the distance between the gradation and the first surface is less than the distance between the gradation and the second surface, such as by at least a factor of 2. Alternatively or additionally it can advantageously be provided that the distance between the gradation and the first surface amounts to 150% to 300% of the height of the functionalized region. In the case of a varying height, this indication again relates to the height present in the region of the relevant opening of the through-hole.

The thickness of the substrate in which the through-hole is formed, corresponding to the distance between the first and second substrate surfaces, can be in the range of 50 μm to 500 μm, for example.

Taking account of the dimensionings or dimensioning rules indicated here, the space requirement (in particular area requirement in the functionalized region) and the reliability of the electrical through-contact can be optimized particularly extensively.

There are diverse possibilities for the embodiment of the through-hole with the at least one gradation. In accordance with one embodiment it is provided that the substrate for this purpose is processed only from the

second surface, that is to say that e.g. firstly a blind hole having a larger hole cross section is formed and then, proceeding from the bottom of this blind hole, the hole section having a smaller cross section by comparison is worked towards the first surface. This processing of the substrate from the second surface can also be carried out in a plurality of (cross-section-reducing) steps. In one alternative embodiment, hole sections produced on the one hand from the second surface and on the other hand from the first surface are supplemented to form the desired through-hole.

The continuous filling of the through-hole with the electrically conductive material may be effected by a liquid filling method, e.g. with a molten solder material. For this purpose, solder materials (e.g. “solder alloys”) known per se can advantageously be used. If appropriate, the substrate surfaces exposed after the formation of the through-hole are passivated before the electrically conductive material is introduced.

By a liquid filling method in accordance with a “one-shot-one-material” method, e.g. by immersing the substrate in a bath of the liquefied electrically conductive material, it is possible for the cavity formed by the through-hole to be filled practically completely with the conductive material with high process reliability.

In one embodiment, the conductive material filled into the through-hole forms a contact, for example so-called “solder ball contact”, at at least one of the two substrate surfaces. The continuous filling of the through-hole and also the formation of a contact at the first and/or second substrate surface can advantageously be carried out in a single process step.

Particularly for producing an electrical contact between the through-contact and the functionalized region at the first substrate surface it can be provided that a contact area which can be wetted with the conductive material is provided at the first surface, the contact area surrounding the opening of the through-hole at the first substrate surface in a ring-shaped manner. When the through-hole is filled with the conductive material, the (e.g. metallic) contact area can thus advantageously be wetted immediately. If a functionalized region is also formed at the second substrate surface, then such a wettable contact area can be provided there as well.

That portion of the conductive material which wets such a contact area can furthermore also constitute a contact to a surface of a directly adjoining further substrate of the relevant integrated circuit, for instance to another substrate that is stacked with the first-mentioned substrate in order to form the integrated circuit.

Particularly for forming an electrical contact with respect to an adjacent substrate in a substrate stack, one particularly advantageous embodiment is an embodiment in which a ring projecting from the second surface is provided in a manner surrounding the opening of the through-hole at the second surface, the ring being filled with the conductive material to an extent such that the conductive material protrudes from the distal end of the ring.

A solderable contact element projecting from the substrate surface in a defined manner can advantageously be provided by such a ring. The ring can be embodied from a polymer material, for example. The height, the internal diameter and the wall thickness of the ring can be defined depending on the application and reliability requirements. Dimensionings suitable for many applications are, for example, a height of from 30 μm to 100 μm, for

example approximately 40 μm, an internal diameter in the range of from 30 μm to 200 μm, for example approximately 50 μmm, and a wall thickness in the range of from 20 μm to 200 μm, for example approximately 50 μm. Quite generally, a wall thickness of at least 10% of the internal diameter and/or at most 100% of the internal diameter is advantageous.

On account of the rather small dimensions of the ring, the latter may not fitted as a “separate component”, but rather produced by a patterning process, for which purpose it is possible to have recourse to methods known per se for the microstructuring of substrate surfaces, in particular methods known from the semiconductor industry. The production of a ring composed of plastics material (e.g. polymer) can accordingly be carried out for example in such a way that the relevant substrate surface is firstly provided with a plastic film or coating over the whole area and a large-area removal (e.g. etching) of the plastic material is then carried out using photolithographic methods (e.g. using photoresists), wherein the relevant material is left only at the desired location or locations on the rings.

The ring (e.g. composed of polymer) can advantageously lead to a stabilization of the material portion (e.g. “solder ball”) protruding from the ring end in the plane and thus to an increase in reliability. Moreover, the ring can reduce a shear effect between soldered substrate and support (e.g. another substrate or “circuit carrier” in a substrate stack), which can arise in the event of thermal loading on account of different linear expansions of the joining partners.

If liquid filling of the through-hole (e.g. with a liquefied solder) is carried out during the production of the electrical through-contact, then, in the case of a non-wettable ring surface, fillings often occur which do not extend as far as the distal ring end or protrude

from the ring end. This can remedied e.g. by an additional coating of the connecting element (e.g. polymer ring) with a wettable layer (e.g., metallic layer). In particular, the ring can have, at its distal end side and, if appropriate, additionally at its outer circumferential surface, a coating that can be wetted with the relevant filling material. Such coatings can also be realized e.g. using photolithographic methods or the like.

If it is desired to save the outlay on such a coating, then a reservoir for the conductive material can be provided in the design of a non-wettable ring, e.g., with large surface area in conjunction with relatively small volume, for example in the form of one or more radial indentations on the inner lateral surface of the ring. When the conductive material is introduced into the through-opening and the ring attached thereto, the reservoir also fills with the material, which does not protrude from the ring end in this situation. However, if the material (solder) is then remelted, e.g., under a protective gas, then the total surface area of the material in the ring decreases and it is possible to bring about the formation of a spherical ball which then protrudes from the ring.

The term “ring” should be understood very broadly here, for instance as an elevation closed in a ring-shaped manner on the relevant substrate surface in the region of an opening of a relevant through-hole. Particularly if such a ring is intended to be provided with a material reservoir of the type mentioned above, then the ring can also have, in particular, a non-circular outer circumference.

In one embodiment, the integrated circuit includes a plurality of substrates which are arranged in a stacked manner and are electrically contact-connected to one another, wherein at least one of the substrates is provided with at least one electrical through-contact as described above.

By way of example, such a circuit can be composed of three substrates stacked one above another. A bottommost substrate can function as a circuit carrier, for example, wherein at the top side conductor tracks and wettable (e.g. metallic) contact areas are provided, via which the electrical connection to the substrate arranged thereabove (middle substrate in the stack) is produced. The middle substrate can have for this purpose e.g. a plurality of electrical through-contacts of the type already described above, e.g. with connecting elements in the form of rings at the substrate underside from which protrudes conductive material (from the associated through-hole). The through-contacts can lead to the top side of this substrate and a functionalized region (microelectronic circuit arrangement) arranged there and/or form at the substrate top side in turn electrical contacts for electrically linking the third, topmost substrate in the substrate stack. The topmost substrate can therefore in turn have electrical through-contacts which connect its underside to the top side, wherein a functionalized region can again be provided e.g. at the top side (alternatively or additionally underside) of the topmost substrate. The electrical through-contacts of the middle substrate and of the upper substrate can be arranged e.g. at least partly coaxially with respect to one another, such that in this case electrical through-contacts are formed from the underside of the middle substrate through to the top side of the upper substrate.

The method for producing an electrical through-contact in a substrate for an integrated circuit includes:
forming a through-hole extending from a first substrate surface to an opposite second substrate surface through the substrate (e.g., with subsequent passivation of the inner surface of the hole), wherein
the through-hole is formed with at least one gradation at which a transition takes place from a smaller hole cross section on the part of the first substrate surface to a larger hole cross section on the part of the second substrate surface,
continuously filling the through-hole with an electrically conductive material.

The through-hole can be formed, in particular, by an etching process in which the substrate is etched from both substrate surfaces (with different hole cross sections), such that the hole gradation arises at the location at which the two (coaxial) partial etchings “meet one another”. After the complete passivation of the inner surface (relief) of the through-hole that is then be carried out, for example by a CVD method or the like, it is possible to effect complete, continuous filling without material transitions with a (single) electrically conductive material between the two substrate surfaces. This may take place by a liquid filling method of the type already explained above. This results in a homogeneous “one-material” filling of the structure.

The particular configurations and developments already described further above for the integrated circuit and/or the electrical through-contact thereof can also be provided in an analogous manner, individually, or in any desired combinations, for the production method.

### BRIEF DESCRIPTION OF THE DRAWINGS

These and other aspects and advantages will become more apparent and more readily appreciated from the following description of exemplary embodiments with reference to the accompanying drawings, in which schematically and in a manner not to scale:

FIGS. 1A to 1C are schematic diagrams (partial cross sections in FIGS. 1B and 1C) illustrating the production of an electrical through-contact in a substrate of an integrated circuit in accordance with a first exemplary embodiment,

FIGS. 2A to 2C are schematic diagrams (partial cross sections in FIGS. 2B and 2C) illustrating such a method in accordance with a further exemplary embodiment,

FIGS. 3A to 3C are schematic diagrams (partial cross sections in FIGS. 3B and 3C) providing an illustration for elucidating a configuration of an electrical connecting element of the electrical through-contact that is modified compared with the example from FIG. 1,

FIGS. 4A to 4C are partial cross section scematic diagrams illustrating an exemplary embodiment of the production of an integrated circuit made from a plurality of stacked substrates, and

FIG. 5 is a partial cross section scematic diagram illustrating the arrangement of the substrate stack from FIG. 4 onto a further substrate, functioning as circuit carrier.

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

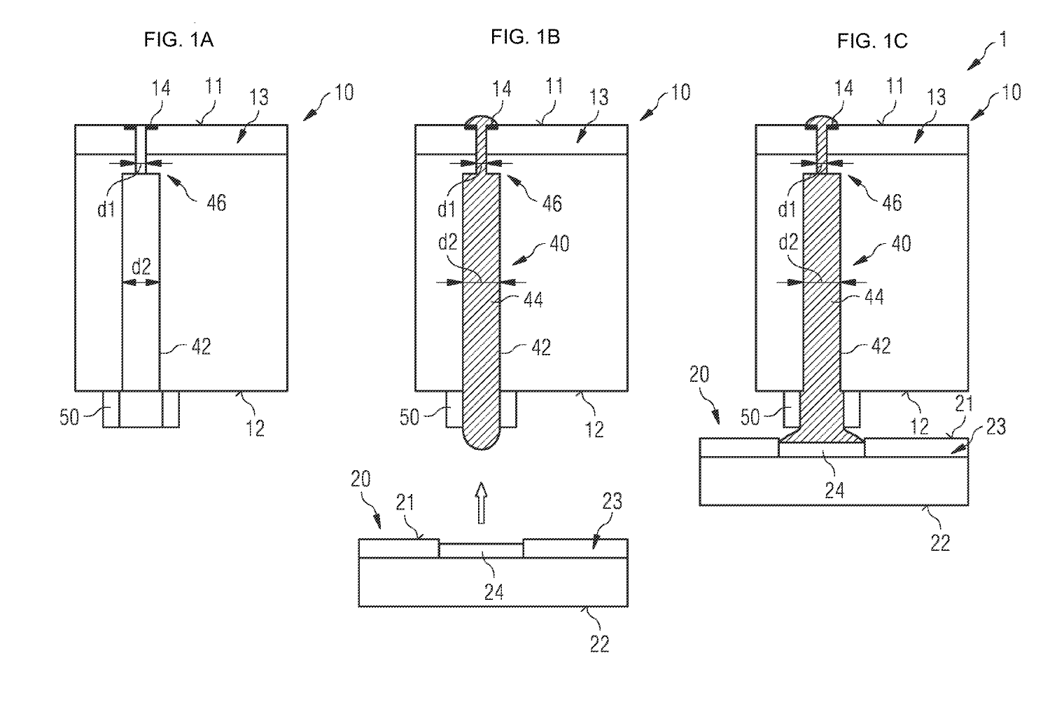

FIGS. 1a to 1c illustrate the production of an integrated circuit 1 having a stacked arrangement composed of a first substrate 10 and a second substrate 20.

Referring to FIG. 1c, the construction of the already finished produced integrated circuit 1 will firstly be described below.

In the example illustrated, the substrates 10, 20 form a first (upper) substrate (10) and a second (lower) substrate (20) of the substrate stack.

The substrate 10 has an (upper) first substrate 11 and an opposite (lower) second surface 12. The substrate 20 has an (upper) first surface 21 and an opposite (lower) second surface 22.

By way of example, silicon can be provided as material for the substrates 10, 20. However, in particular all materials that are customary in the semiconductor industry for producing microelectronically integrated circuits also come into consideration.

In the example illustrated, the lower substrate 20 merely constitutes a circuit carrier or a printed circuit board and thus serves principally for the electrical “wiring” of the substrate 10 arranged thereon and for affording possibilities for externally making contact with the integrated circuit 1. In this respect, specifically the substrate 20 can e.g. also be produced from a ceramic material or epoxy resin or other electrically insulating materials, but electrically conductive regions such as metallic conductor tracks and/or contact areas have to be provided at least at its top side.

Respective “functionalized regions” 13 and 23 are formed at the first surfaces 11 and 21 of the substrates 10 and 20.

These functionalized regions 13 and 23, also designated as functional regions hereinafter, include, in a manner known per se, essential electrical and/or electronic components of the integrated circuit 1, whereas regions situated more deeply within the substrate (“bulk”) principally serve as electrical insulation or carriers for the functional regions 13, 23.

The functional region 13 of the first substrate 10 can include in particular differently doped regions, passivations (e.g. composed of oxides or nitrides (e.g. SiO₂) or else metallizations, in order to provide the respectively desired electronic components (e.g. transistors, diodes, resistors, etc.) and the electrical connections thereof (e.g. produced using CMOS technology or some other suitable technology). As part of the functional region 13, a contact area 14 (e.g. metallized region) is depicted in the figures.

In the example illustrated, the functional region 23 of the second substrate 20 essentially has conductor tracks which lead to various contact areas or connect

such contact areas to one another. Such a contact area 24 (metal layer) is depicted in FIG. 1c. 25 designates a so-called soldering resist layer.

The individual functional regions of the integrated circuit 1 formed from a plurality of substrates are connected to one another via one or a plurality of electrical through-contacts.

Such a through-contact 40 is depicted by way of example in FIG. 1c, the through-contact providing an electrical connection between the contact area 14 of the first substrate 10 and the contact area 24 of the second substrate 20.

In the case of the through-contact 40 it may be formed in a known manner as a through-hole 42 which extends from the first substrate surface 11 to the second substrate surface 12 through the substrate 10 and which (after the passivation of the inner circumferential surface) was filled with an electrically conductive material (the conducive material is illustrated in a hatched manner in the figures). In the example illustrated, the conductive material is a solder 44 composed of metal or a metal alloy (e.g. having a melting point in the range of 150° C. to 300° C.). In the case of the example illustrated, it is also known for a hole cross section of the through-hole 42 to be circular. However, one special feature of the through-contact 40 is that the through-hole 42 has a gradation 46 at which a transition takes place from a smaller hole diameter d1 on the part of the first surface 11 to a larger hole cross section d2 on the part of the second surface 12. In other words, at the gradation 46 the hole cross section decreases as viewed over the length of the through-hole 42 in the direction from the second surface 12 to the first surface 11.

During the production of the integrated circuit 1 (FIG. 1c), the following procedure was adopted:

Firstly, as illustrated in FIG. 1a, the first substrate 10 (here: semiconductor substrate, e.g. silicon) was processed in order to form at the top side (first surface 11) the functional region 13 and the through-hole 42 extending through the substrate 10. For this purpose, it is advantageously possible to have recourse to processes known per se in the semiconductor industry (e.g. CMOS technology). The through-hole 42 can be formed e.g. with the aid of customary methods such as anisotropic etching, dry etching, anisotropic wet etching, etching with the support of an electric field or laser etching, wherein, in the example illustrated, the gradation 46 mentioned is produced at a location in the course of the hole, at which gradation, in the example illustrated, a transition takes place from the smaller hole diameter d1=5 μm (on the part of the first surface 11) to the larger hole diameter d2=100 μm.

In the example illustrated, the gradation 46, as viewed in the height direction, is situated relatively closely (e.g. less than 10 μm, in particular less than 5 μm) below the functional region 13. At the second surface 12, in the region of the opening of the through-hole 42, a ring-shaped elevation, here a ring 50 composed of polymer material, is arranged coaxially with respect to the through-hole 42, the inner cross section of the ring corresponding approximately to the hole cross section at this location.

The through-hole 42 (including the ring 50) is then filled continuously and completely with the electrically conductive material, with the solder 44 in the example illustrated. This “void-free” filling of the entire hole relief in “one shot” and with a single material takes place by a liquid filling method in which the substrate 10 is completely immersed in a bath of the liquefied solder 44 (e.g. at a temperature of more than 150° C.) under vacuum, for example, wherein an increase in pressure after immersion has the effect that the liquefied solder is forced into the through-opening. After the removal of the substrate 10 from the solder bath (and solidification of the solder 44), the state illustrated in FIG. 1b results, for example, in which the through-hole 42 is filled completely and homogeneously with the electrically conducive material (solder 44), wherein the metallic contact area 14 was wetted at the top side of the substrate and a convex overhang of a portion of the solder 44 is present at the distal end of the polymer ring 50 at the underside of the substrate. The ring 50 serves as it were as a delimiting ring for laterally delimiting the solder 44 protruding at the lower opening of the through-hole 42 and forms together with this solder 44 an advantageous electrical “connecting element” for contact-connecting the through-contact 40 to another substrate or circuit carrier. The ring 50 (or some other elevation which is closed in a ring-shaped manner and serves for this purpose) was formed at the second surface 12 of the substrate 10 e.g. by a photolithographic method.

In the example illustrated, as illustrated at the bottom in FIG. 1b, the second substrate 20 is then attached to the first substrate 10 in such a way that electrical contact is made with the through-contact 40 at the metallic contact area 24 of the functional region 23 of the second substrate 20. This may take place at suitably elevated temperature, such that the portion of the solder 44 protruding from the ring 50 in this case wets the contact area 24 well.

This results in the structure illustrated and already described in FIG. 1c, in which structure the integrated circuit 1 is formed from the two substrates 10 and 12 attached to one another vertically in a stacked manner. It goes without saying that the substrate 10 can in practice be provided with a multiplicity of through-contacts of the type illustrated which are formed e.g. simultaneously by the same process. The vertical stacking illustrated in the exemplary embodiment illustrated in no way precludes additionally also carrying out a horizontal stacking or juxtaposition of substrates. In the example illustrated, the second substrate 20 functioning as circuit carrier could carry for example a plurality of the substrates (such as the substrate 10 illustrated) arranged thereon (alongside one another).

The particular configuration of the through-contact 40 advantageously makes it possible to construct geometrically space-saving multifunctional systems in which a plurality of substrates can be combined to form an integrated circuit in a manner stacked not only laterally but alternatively or additionally also vertically. A through-contact, in which a particularly small hole cross section or hole diameter is provided at least at one substrate surface (at which a functionalized region is formed), saves valuable surface area in the region of the functionalized region, on account of the larger hole cross section within the substrate a continuous filling of the through-hole is nevertheless accomplished well with high quality (in particular without inclusions). The basic concept of the exemplary embodiment in accordance with FIGS. 1A to 1C involves dividing the through-contact 40 into three regions which have special features specifically adapted to the respective functionality: in the active region (functional region 13) the through-hole 42 has a relatively small diameter, thus resulting in a high efficiency of the area utilization in the region of the first surface 11. By contrast, a relatively large hole cross section is provided in the “bulk” of the substrate 10, and, in a departure from the exemplary embodiment illustrated, could also increase in a multi-step manner toward the second surface 12. This results in a filling with fewer problems, and also advantageously in a high electrical conductivity. The connecting element provided at the second surface 12, such as in particular the polymer enclosure realized by the ring 50, finally advantageously improves the thermomechanical reliability of the electrical contact thereby realized.

These three regions can advantageously be filled in one process, with one solderable, conductive material (here: solder 44) without additional more complicating measures and thus produced simultaneously. That simplifies the process and increases the product reliability.

In other words, in the example illustrated, a stepped through-contact 40 is provided which is integrated together with the electrical connecting element (“solder bump”) to form a continuous and homogeneous electrical conductor without “interfaces”. The mechanical support of the solder portion used for contact-making by the delimiting ring 50 considerably extends the functionality of the through-contact 40.

The method thus enables advantageous stackings of a plurality of substrates with a “3D contact-connection”.

In the following description of further exemplary embodiments, for components acting identically the same reference numerals are used, in each case supplemented by a lower-case letter in order to distinguish the embodiment. Here essentially only the differences relative to the exemplary embodiment or exemplary embodiments already described will be discussed, and for the rest reference is hereby expressly made to the description of previous exemplary embodiments.

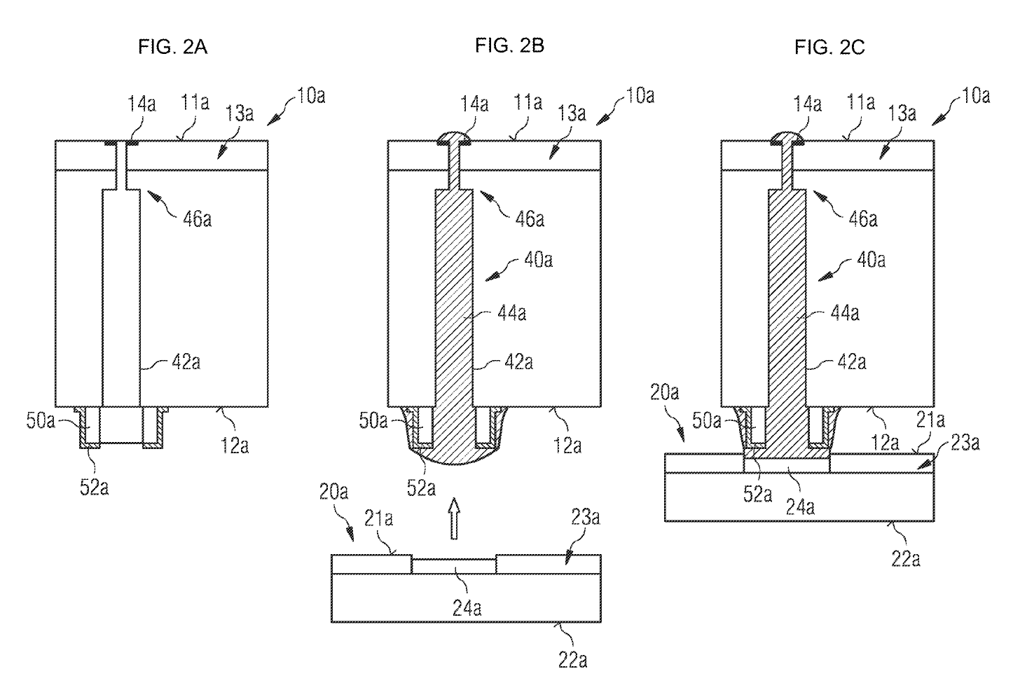

FIGS. 2a to 2c show a modified exemplary embodiment in an illustration corresponding to FIGS. 1a to 1c.

The modification relative to the exemplary embodiment already described involves a polymer ring 50a arranged at the underside of a first substrate 10a is provided with a wettable coating 52a, which, in the example illustrated, proceeding from the distal end face of the ring 50a, also extends over the entire lateral surface of the ring 50a.

When the relevant through-hole 42a is filled with a liquefied solder 44a, the portion of the solder 44a emerging from the distal end of the ring 50a wets the metal coating 52a, which, in the liquid filling process, promotes the formation of a reliable electrical connecting element by the ring 50a.

Otherwise, the explanations already given above for the exemplary embodiment in accordance with FIG. 1 hold true for the exemplary embodiment in accordance with FIG. 2.

What is common to the examples in accordance with FIG. 1 and FIG. 2 is that solder material projects at the underside of a first substrate or the delimiting ring formed there. In accordance with one embodiment, this solder overhang has a convex shape, for which, in the case of a non-wettable ring material (e.g. polymer), the above-mentioned coating composed of a wettable material (metal coating (52a) is advantageous.

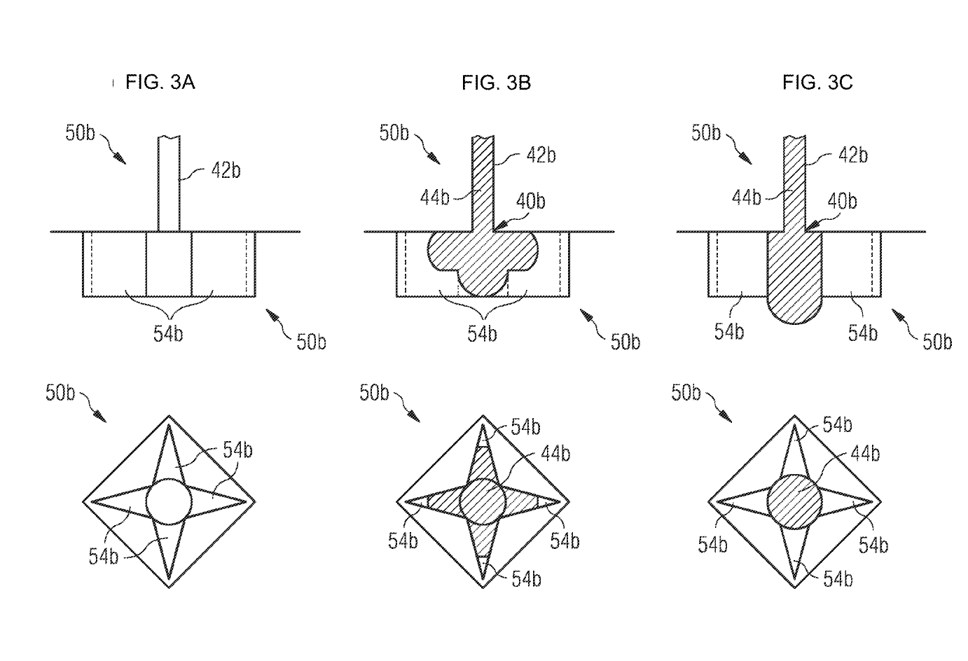

An alternative possibility for improving the formation of a “solder ball” at the distal end of a delimiting ring is illustrated by the configuration of a (likewise non-wettable) ring 50b, e.g. once again composed of polymer material, as shown by way of example in FIG. 3.

Subfigures 3a to 3c illustrate different stages of the filling process. FIG. 3a shows the still unfilled state. A special feature of the ring 50b is that the ring has, proceeding from an approximately cylindrical central cavity, protuberances 54b which project outward in a star-shaped manner and which function as a solder reservoir for the solder 44b subsequently introduced.

As illustrated in FIG. 3b, a certain amount of the solder 44b can be introduced in the protuberances 54b, particularly if, on account of the lack of wettability of the ring material, for example, no overhang of the solder 44b is formed at the distal end of the ring 50b. This situation is illustrated in FIG. 3b.

After such filling of the through-hole 42b and of the ring 50b together with the reservoir (protuberances 54b) thereof, the solder 44b can be remelted, however, in which case the total surface area of the solder 44b in the ring 50b decreases and a more or less spherical ball (solder ball) arises which then also projects from the ring 50b. This situation is illustrated in FIG. 3c.

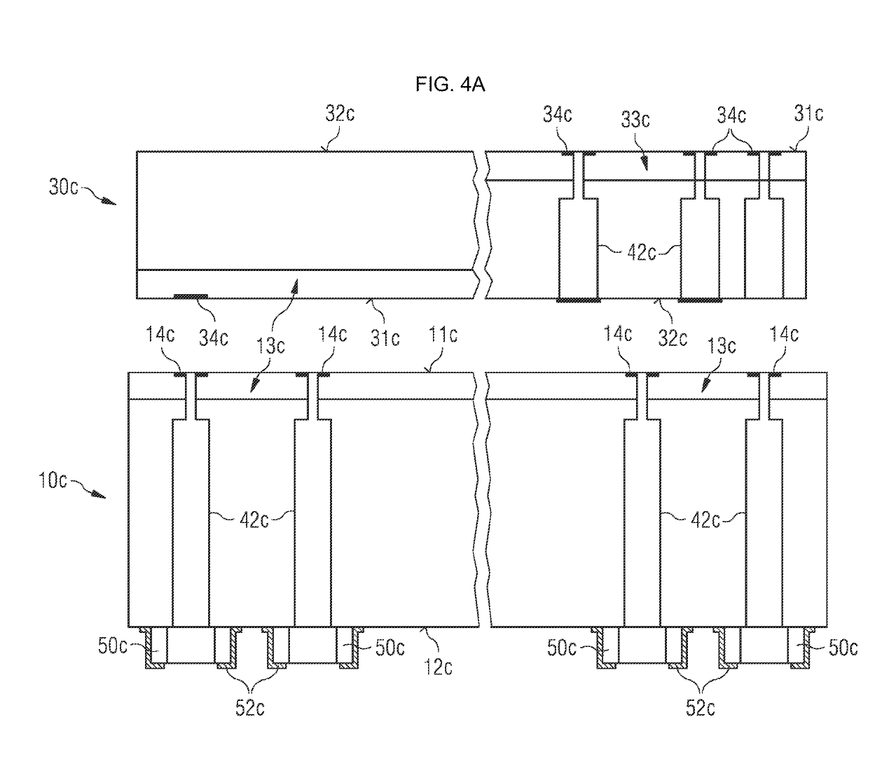

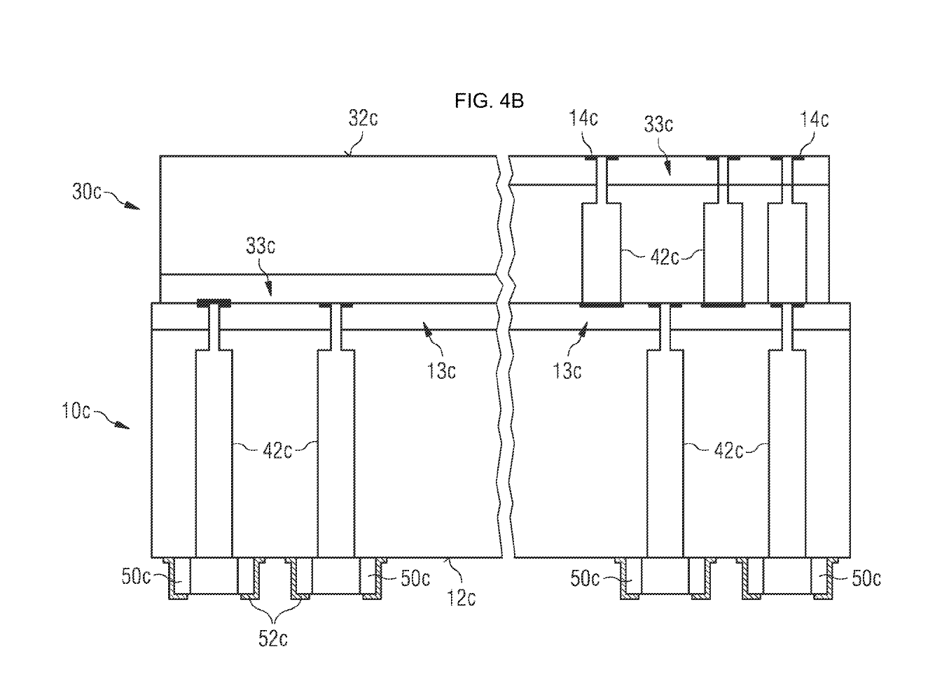

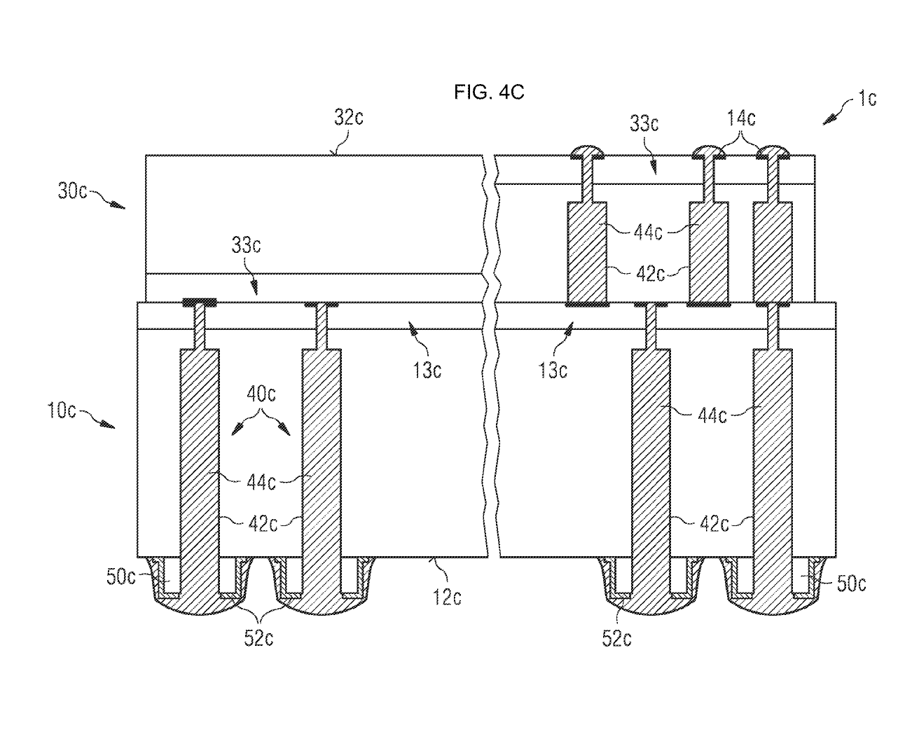

FIGS. 4a to 4c show a further exemplary embodiment of the production of an integrated circuit 1c (FIG. 4c).

As illustrated in FIG. 4a, firstly two substrates 10c and 30c are produced separately and provided at least partly with through-holes 42c of the type already described above. The substrate 10c illustrated in FIG. 4a corresponds, in terms of the embodiment, to the example already explained and shown in FIG. 2a. In the illustration of the substrate 30c, two variants have been depicted simultaneously in FIG. 4a, namely with functional region 33c facing toward the first substrate 10c in the left-hand part of the figure and with functional region 33c facing away from the substrate 10c in the right-hand part of the figure. The first and second surfaces of the substrate 30c are designated by 31c and 32c, respectively.

As evident from FIG. 4b, the two substrates 10c and 30c are then positioned and stacked with respect to one another. In this case, the substrate 30c is stacked on the (upper) first surface 11c of the first substrate 10c.

The substrate stack illustrated in FIG. 4b is then subjected to a liquid filling process, for example as already described above (by immersing the substrate stack in a bath of molten solder), in order to fill the through-holes 42c and connecting element rings 50c situated at the (lower) second surface 12c of the substrate 10c in “one shot” with solder 44c.

This results in the state which is shown in FIG. 4c and in which the through-holes 42c are filled homogeneously and continuously with solder 44c and in this case the corresponding through-contacts 40c are simultaneously completed as well.

As evident from FIG. 4c, there are a wide variety of possibilities with regard to the electrical connections produced by the through-contacts 40c.

By way of example, for the through-contact 40c depicted on the far left of FIG. 4c, it is provided that an electrical contact with contact areas both of the substrate 10c and of the substrate 30c is provided at the upper end. In the case of the through-contact 40c that is adjacent on the right in the figure, by contrast, only one contact with a contact area is provided at the upper end in the functional region 13c of the substrate 10c. Further (self-explanatory) variants of the electrical connections produced are evident from the right-hand part of FIG. 4c.

For example in order to enclose the integrated circuit 1c shown in FIG. 4c in a customary housing (epoxy resin encapsulation) and to be able to provide an electrical connection from such a housing, finally the electrical connecting elements (rings 50c with portions of solder 44c protruding therefrom) formed at the underside of the substrate 10c can be placed onto a further substrate 20c, serving as circuit carrier, and thus be contact-connected, as is illustrated in FIG. 5.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-8. (canceled)

9. An integrated circuit, comprising
a substrate, having a first surface and a second surface opposite thereto, with a functionalized region formed at least at the first surface, and at least one electrical through-contact provided as a through-hole extending from the first surface to the second surface through the substrate and filled continuously with an electrically conductive material, the through-hole having at least one gradation at which a transition takes place from a smaller hole cross section at the first surface to a larger hole cross section at the second surface.

10. The integrated circuit as claimed in claim 9, wherein a diameter of the smaller hole cross section is less than 20 μm.

11. The integrated circuit as claimed in claim 10, wherein the diameter of the smaller hole cross section is less than 10 μm.

12. The integrated circuit as claimed in claim 11, wherein the diameter of the smaller hole cross section is less than 200% of a height of the functionalized region.

13. The integrated circuit as claimed in claim 12, wherein the diameter of the smaller hole cross section is less than 100% of the height of the functionalized region.

14. The integrated circuit as claimed in claim 13, wherein diameters of the smaller hole cross section and of the larger hole cross section differ from one another by at least a factor of 2.

15. The integrated circuit as claimed in claim 14, wherein a first distance between the gradation and the first surface is less than a second distance between the gradation and the second surface.

16. The integrated circuit as claimed in claim 15, further comprising a ring projecting from the second surface and surrounding an opening of the through-hole at the second surface, the ring being filled with the electrically conductive material so that the electrically conductive material protrudes from a distal end of the ring.

17. The integrated circuit as claimed in claim 16, wherein the substrate constitutes one of a plurality of substrates arranged in a stacked manner and electrically contact-connected to one another.

18. A method for producing an electrical through-contact in a substrate for an integrated circuit, comprising:
forming a through-hole extending from a first surface of the substrate to a second surface of the substrate opposite the first surface, through the substrate, the through-hole having at least one gradation at which a transition takes place from a smaller hole cross section at the first surface to a larger hole cross section at the second surface; and
continuously filling the through-hole with an electrically conductive material.
